(19) United States
(12) Patent Application Publication
(10) Pub. No.: US 2026/0005596 A1
(43) Pub. Date: Jan. 1, 2026

(54) METHODS AND APPARATUS TO CONTROL A VOLTAGE CONVERTER

(71) Applicant: Texas Instruments Incorporated, Dallas, TX (US)

(72) Inventors: Shishuo Zhao, Allen, TX (US); Eric Warren Southard, Richardson, TX (US); Daniel Andrew Mavencamp, Rockwall, TX (US); Richard Kane Stair, Knoxville, TN (US)

(21) Appl. No.: 18/757,246

(22) Filed: Jun. 27, 2024

(51) Int. Cl. H02M 1/08; H02M 3/158; H03K 19/20

(52) U.S. Cl. CPC H02M 1/08; H02M 3/1582; H03K 19/20

(57) ABSTRACT

An example apparatus includes: a comparator including a first input terminal, a second input terminal, and an output terminal, the first input terminal to be coupled to a source of a comparison of an output terminal of a buck converter and an input terminal of the buck converter, the second input terminal to be coupled to a source of a signal indicative of a threshold; and circuitry including a first input terminal, a second input terminal, and an output terminal, the first input terminal of the circuitry coupled to the output terminal of the comparator, the second input terminal of the circuitry coupled to a signal indicative of whether a first operation mode of the buck converter is requested, the output terminal of the circuitry to indicate the first operation mode of the buck converter or a second operation mode of the buck converter.

### TECHNICAL FIELD

This description relates generally to voltage converters and, more particularly, to methods and apparatus to control a voltage converter.

### BACKGROUND

A voltage converter converts an input voltage level to an output voltage level that is appropriate for a particular application. For example, a voltage converter may step down an input voltage of 20 volts to an output voltage of 13.5 volts to match a charging voltage for a 3 cell in series (3S) 4.5 volt battery pack or an output voltage at 18 volts to match a charging voltage for a 4 cell in series (4S) 4.5 voltage battery pack. In another example, a voltage converter may step up a 10 volt input voltage to 13.5 volts or 18 volts output.

A buck-boost converter is a type of direct current (DC)-DC converter that can produce an output voltage that is either higher or lower than the input voltage. The buck-boost converter can operate in two distinct operating modes: a "buck" mode in which the output voltage is lower than the input voltage, and the "boost" mode in which the output voltage is higher than the input voltage. The buck-boost converter can smoothly transition between these two modes via a buck-boost mode.

A buck-boost converter operates using one or more switches (e.g., transistors), which control current flow through an inductor and a capacitor. During a switch's ON state, energy is stored in the inductor, and during the OFF state, the energy is transferred to the output through the diode. The duty cycle of the switch, or the ratio of ON time to the total period of the switching cycle, determines the converter's output voltage. Adjusting the duty cycle allows the output voltage to be controlled and maintained at the desired level.

### SUMMARY

For controlling a voltage converter, an example apparatus includes a comparator including a first input terminal, a second input terminal, and an output terminal, the first input terminal to be coupled to a source of a comparison of an output terminal of a buck converter and an input terminal of the buck converter, the second input terminal to be coupled to a source of a signal indicative of a threshold; and circuitry including a first input terminal, a second input terminal, and an output terminal, the first input terminal of the circuitry coupled to the output terminal of the comparator, the second input terminal of the circuitry coupled to a signal indicative of whether a first operation mode of the buck converter is requested, the output terminal of the circuitry to indicate the first operation mode of the buck converter or a second operation mode of the buck converter. Other examples are described.

For controlling a voltage converter, an example apparatus includes a first comparator including a first input terminal, a second input terminal, and an output terminal, the first input terminal of the first comparator to be coupled to a signal indicative of an input current to a buck converter, the second input terminal of the first comparator to be coupled to a signal indicative of a threshold; and a logic gate including a first input terminal, a second input terminal, and an output terminal, the first input terminal of the logic gate coupled to the output terminal of the first comparator, the second input terminal of the logic gate coupled to a signal indicative of whether a first operation mode of the buck converter is requested, the output terminal of the logic gate to indicate the first operation mode of the buck converter or a second operation mode of the buck converter. Other examples are described.

For controlling a voltage converter, an example apparatus includes a buck converter circuit including a plurality of transistors to convert an input signal at a first voltage to an output signal at a second voltage; a controller to control operation of the transistors of the buck converter circuit including controlling the buck converter circuit to operate in at least a first operation mode and a second operation mode; and a shutoff circuit to receive an input signal indicative of a request for the first operation mode and, in response, to selectively indicate to the controller to operation in the first operation mode or the second operation mode based on the input signal. Other examples are described.

### BRIEF DESCRIPTION OF THE DRAWINGS

FIG. 1 is a block diagram of an example environment in which a buck-boost converter charges a battery to supply a load.

FIG. 2 is a block diagram of an example implementation of the shutoff circuit.

FIG. 3 is a schematic diagram of example circuitry that includes an example implementation of the switching network, an example implementation of the converter, and an example implementation of the battery.

FIG. 4 is a schematic diagram of example circuitry that includes an example implementation of the switching network, an example implementation of the converter, and an example implementation of the battery.

FIG. 5 is a state diagram illustrating an operation of the controller of FIG. 1.

FIG. 6 is a block diagram of an example implementation of the shutoff circuit.

FIG. 7 is a schematic diagram of example circuitry that includes an example implementation of the switching network, an example implementation of the converter, and an example implementation of the battery.

FIG. 8 is a schematic diagram of example circuitry that includes an example implementation of the switching network, an example implementation of the converter, and an example implementation of the battery.

FIG. 9 is a state diagram illustrating an operation of the controller of FIG. 1.

The drawings are not necessarily to scale. Generally, the same reference numbers in the drawing(s) and this description refer to the same or similar (functionally and/or structurally) features and/or parts. Although the drawings show regions with clean lines and boundaries, some or all these lines and boundaries may be idealized. In reality, the boundaries or lines may be unobservable, blended, or irregular.

### DETAILED DESCRIPTION

Battery cell operating voltage is increasing to increase battery capacity and battery life. Currently, product makers are using a number of 4.5V cells to create batteries. For example, four 4.5 V cells may be combined to form a 4S battery having an operating voltage of 18V, or three 4.5 V cells may be combined to form a 3S battery having an operating voltage of 13.5V. Adapter voltage received by the battery charger for battery charging may be reduced under heavy load due to long input cable current (I)*resistance(R) voltage drops in the adapter. Also, adapter voltage tolerances can cause the output voltage to the battery charger to be lower than a nominal voltage. As a result, the input voltage a charger receives from an adapter could be reduced from, for example, 20V to 18.5V for a 20V adapter, or from 15V to 14V for a 15V adapter.

When battery charging systems utilize a buck-boost converter, operating in buck-boost mode for an extended time period may result in power inefficiencies and thermal concerns under high power conditions. For example, when a battery is fully charged the voltage of the battery (VBAT) may start to approach the input voltage of the converter (VIN). This situation may be more prevalent due to I*R drop in cabling that reduces the VIN. These factors tend to trigger the converter transition from buck mode to buck-boost mode. However, buck-boost mode holds lower efficiency than buck mode under the same VIN / VOUT conditions due to larger inductor current ripple and higher switching loss.

For applications in which the designer of a charging system knows that the input voltage is higher than the output voltage of the converter, high-duty-cycle buck mode can be employed to improve buck-boost charger efficiency. In high-duty-cycle buck mode, the voltage converter is controlled to stay in buck mode, even when it would normally transition to buck-boost mode. For example, in high-duty-cycle buck mode, a boost high-side switch (e.g., metal oxide semiconductor field effect transistor (MOSFET)) may be kept permanently on or on for extended periods. One side-effect of utilizing high-duty-cycle buck mode is a reverse boost-back condition, which can appear when a power adapter is disconnected, or an input voltage drops lower than VBAT. In such situations, the VIN terminal of the charger may be reverse-powered by the battery and an undesirable battery current drain may occur, which are both undesirable. In some systems, embedded controller firmware is utilized to avoid the reverse boost-back issue when VOUT / VIN changes. However, such embedded controller approaches are complicated and expensive.

Methods and apparatus described herein utilize an input to indicate whether high-duty cycle buck mode is requested. When the input is enabled, the converter will stay in buck mode, even when a standard buck-boost converter would enter buck-boost mode. For example, as the converter approaches 100% duty cycle (VOUT/VIN< high-duty cycle exit comparator (HDEC)), instead of entering buck-boost mode, it will skip the low side switch turn on pulse and keep the boost high side switch on, effectively increasing the equivalent duty cycle and efficiency. For example, when the high-duty cycle buck mode is not enabled, the converter may operate in buck mode when VOUT/VIN is less than a first threshold (e.g., 90%), may operate in buck-boost mode when VOUT/VIN is between the first threshold and a second threshold (e.g., 130%), and may operate in boost mode when VOUT/VIN is greater than the second threshold. According to examples described herein, when high-duty cycle buck mode is enabled, the converter may operate in buck mode when VOUT/VIN is less than a first threshold (e.g., 80%), may operate in buck-boost mode when VOUT/VIN is between the first threshold and a high-duty cycle exit condition HDEC threshold (e.g., 90%), may operate in buck-boost mode when VOUT/VIN is between the HDEC and a second threshold (e.g., 130%), and may operate in boost mode when VOUT/VIN is greater than the second threshold.

In some implementations, rather than controlling operation solely based on the high-duty cycle input, the methods and apparatus described herein monitor the conditions of the converter to override the input under certain conditions to automatically transition back to normal buck-boost mode. For example, by automatically overriding a request for high-duty cycle buck mode, a reverse boost-back condition can be avoided (e.g., when a power adapter is disconnected or the input voltage otherwise drops below output (e.g., VBAT).

For example, in one implementation, an output voltage of the converter is compared with an input voltage of the comparator and the request to enable high-duty cycle mode is overridden when VOUT is within a threshold of VIN (e.g., when VOUT divided by VIN is greater than or equal to 99%). In another implementation, an input current for the converter is monitored to detect when a load on the converter is low (e.g., the battery is approaching full charge) and to override the high-duty-cycle buck mode to transition the converter to normal buck boot mode.

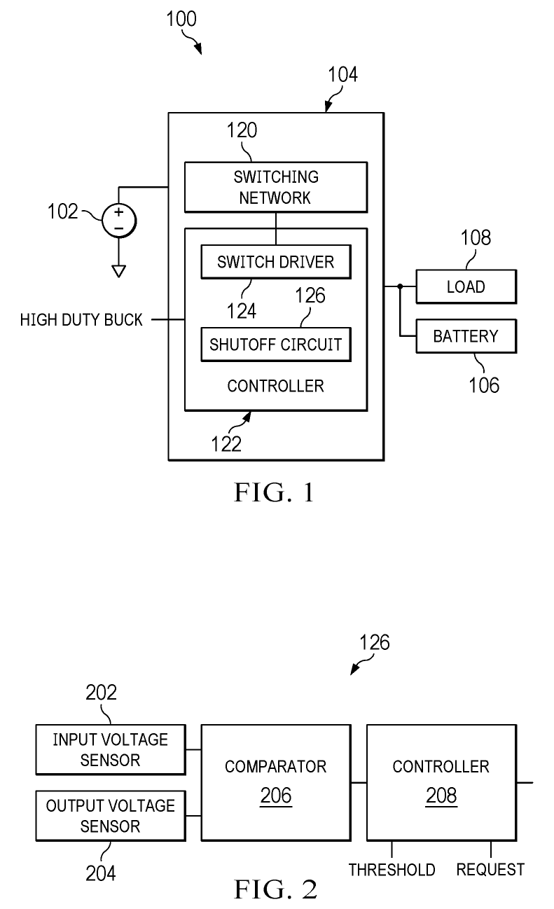

FIG. 1 is a block diagram of an example environment 100 in which a buck-boost converter 104 charges a battery 106 to supply a load 108. The example environment 100 includes an input supply 102, the buck-boost converter 104, the battery 106, and the load 108.

The input supply 102 supplies DC power to the converter 104. For example, the input supply may be the output of an alternating current (AC) to DC transformer, a DC power supply, etc.

The converter 104 is a buck-boost converter that includes a switching network 120 and a controller 122.

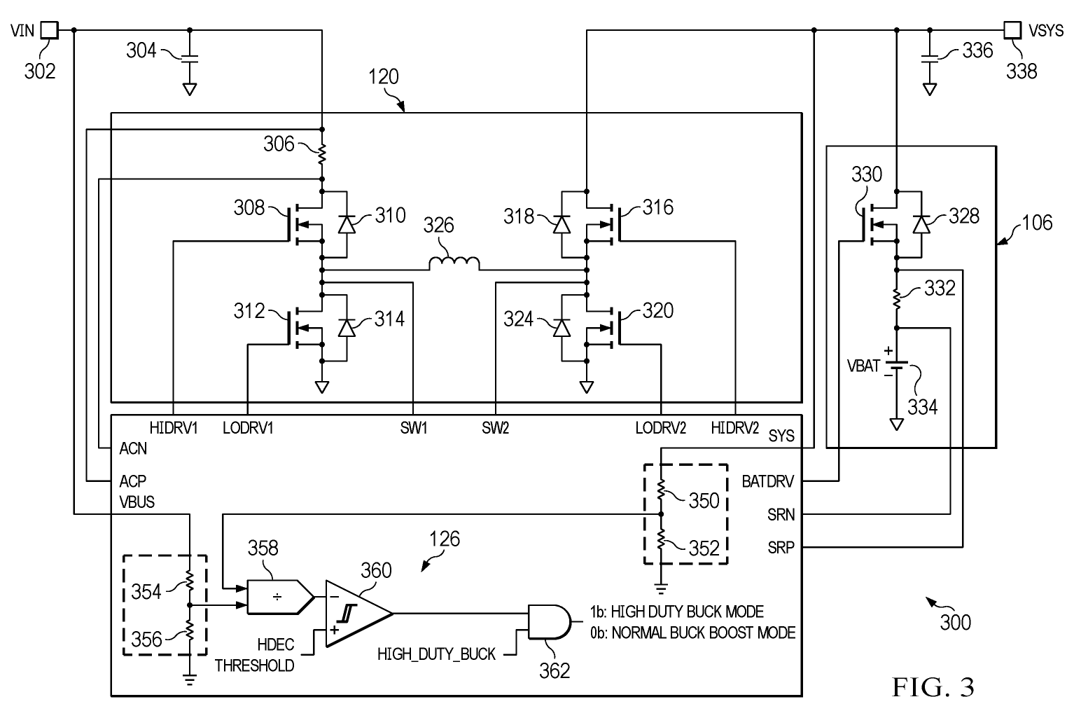

The switching network 120 includes one or more switches, capacitors, and inductors to deliver a desired voltage output based on a variable or fixed input voltage. By systematically controlling the switches of the switching network 120, the input voltage may be increased or decreased produce the output voltage. The example switches are implemented by transistors, however any other type of switching and components may be utilized. Example implementations of the switching network 120 are illustrated in FIGS. 3, 4, 7, and 8. Alternatively, any other type of switching network for implementing a converter such as a buck-boost converter may be utilized.

The controller 122 is circuitry to output signals to drive the switches of the switching network 120. The example controller 122 includes a switch driver 124 and a shutoff circuitry 126.

The switch driver 124 is microcontroller driver circuitry to generate the output signals to control the switching network 120. Alternatively, the controller 122 may be implemented by any type of circuitry to control the operation of the switching network 120 such as, for example, a general-purpose processor, discrete circuit elements, and/or any combination or plurality of circuitry components. The switch driver 124 operates the switches of the switching network to implement a boost mode, a buck mode, or a buck-boost mode. For example, the controller 122 may select a mode based on the conditions of the circuit including the input voltage, the output voltage, an input current, etc. The example switch driver 124 accepts an input (high-duty buck request) to indicate if the switch driver 124 is to utilize high-duty buck mode. For example, when high-duty buck mode is enabled, the switch driver 124 will control the switches of the switching network 120 to operate in high-duty buck mode. The switch driver 124 may alternatively selectively operate in high-duty buck mode when the high-duty buck mode input is enabled. For example, the switch driver 124 may operate in high-duty buck mode when VOUT/VIN meets a threshold (e.g., VOUT/VIN is greater than or equal to a threshold) at which the switch driver 124 would normally start operating in buck-boost mode (e.g., when VOUT/VIN is between 90% and 110%).

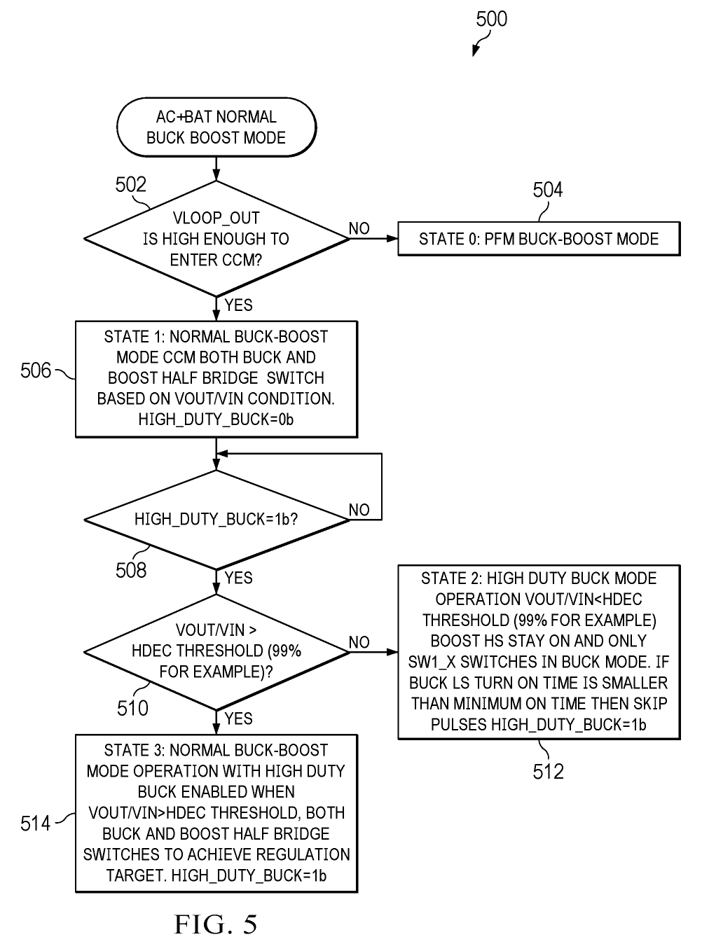

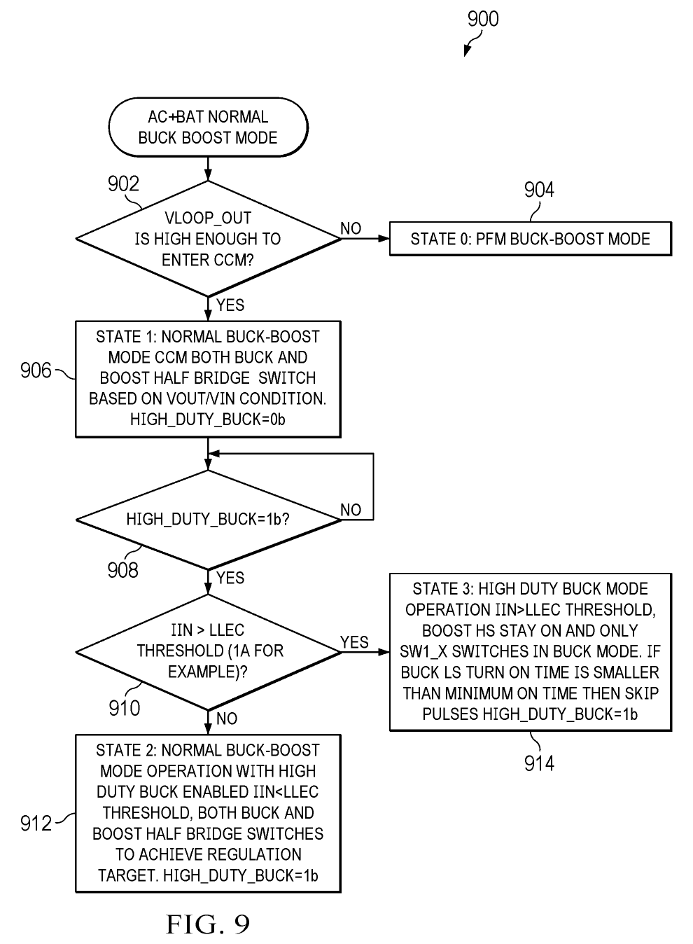

The example shutoff circuit 126 is circuitry to selectively override the request for high-duty buck mode. As previously described, utilizing high-duty buck mode in some circumstances may result in undesirable side effects such as a battery reverse powering battery charger circuitry due to high-duty buck mode keeping a supply-side switch constantly enabled. Accordingly, the shutoff circuity 126 receives the high-duty buck mode request and selectively passes the high-duty buck mode enable request to the switch driver 124. Example circuitry to implement the shutoff circuit 126 is described in conjunction with FIGS. 3, 4, 7, and 8, and example logic to implement the shutoff circuit 126 is described in conjunction with FIGS. 5 and 9.

While the example switch driver 124 and the example shutoff circuit 126 of FIG. 1 are illustrated as separate components, some or all of the functionality of these components may be combined. For example, a single microcontroller may be utilized to implement the entire controller 122.

The example battery 106 and the example load 108 are coupled to the output of the converter 104.

The battery 106 is a battery that is charged by the converter 104 and can supply power to the load 108 when there is no voltage input to the converter 104 (e.g., when the supply 102 is disconnected). The battery 106 may be any type of battery such as, for example, a lithium ion (Li-ion) battery, a nickel cadmium (Ni-Cd) battery, a nickel-metal hydride (Ni-MH) battery, etc. The battery 106 may have a maximum voltage that is less than, equal to, or more than the supply voltage 102. While the battery 106 is charging, the voltage level of the battery 106 is less than the maximum voltage of the battery 106.

The load 108 of the example is a laptop computer. Alternatively, the load 108 may be any type of load that receives power from the converter 104 and/or the battery 106.

While the example of FIG. 1 includes the battery 106 and the load 108, other implementations of the environment 100 may include one of the battery 106 or the load 108 and/or may include any number of batteries (e.g., a battery pack that combines multiple batteries in series and/or parallel) and loads.

In operation of the environment 100, the switching network 120 is controlled by the switch driver 124 in buck mode, buck-boost mode, high-duty buck mode, or boost mode based on the supply 102, the charge state of the battery 106, and a high-duty buck request signal from the shutoff circuit 126. The shutoff circuit 126 monitors the state of the environment 100 such as the output voltage of the converter 104 (e.g., the voltage level of the battery 106), the input voltage to the converter 104 (e.g., the voltage of the supply 102), an input current to the converter 104, etc. Based on the state of the environment 100, the shutoff circuit 126 determines if a request for high-duty buck mode is transmitted to the switch driver 124. In one implementation, the shutoff circuit 126 transmits an input request for high-duty buck unless VOUT approaches VIN (e.g., when VOUT/VIN is greater than 90%).

FIG. 2 is a block diagram of an example implementation of the shutoff circuit 126. The example shutoff circuity 126 of FIG. 2 includes an example input voltage sensor 202, an example output voltage sensor 204, an example comparator 206, and an example controller 208.

The input voltage sensor 202 senses the voltage of the input to the converter 104. For example, the input voltage sensor 202 may be an analog input port of a microprocessor, a voltage divider circuit (e.g., a voltage divider resistor network), etc.

The output voltage sensor 204 senses the voltage the output of the converter 104. For example, the output voltage sensor 204 may be an analog output port of a microprocessor, a voltage divider resistor network, etc. The output voltage sensor 204 may sense the voltage output to the battery 106 and/or the load 108.

The comparator 206 compares the output voltage sensed by the output voltage sensor 204 to the input voltage sensed by the input voltage sensor 202 and outputs the result of the comparison to the controller 208. The example comparator 206 is implemented by division circuitry that divides the output voltage by the input voltage. Alternatively, the comparator 206 may be any other type of circuitry, and/or processor to determine a difference between the output voltage in the input voltage (e.g., a difference in magnitude, a percentage difference, etc.).

The controller 208 compares the difference received from the comparator 206 with a threshold and, based on the comparison, determines whether to output a request for high-duty cycle buck mode. The example controller 208 is implemented by a comparator to compare the difference with the threshold and an AND gate (or other logic circuit) to perform a logical AND of the output of the comparator and an input signal indicative of a request for high-duty cycle buck mode. Alternatively, the controller 208 may be implemented by a microprocessor, a microcontroller, discrete circuit elements, or any combination. According to the example of FIG. 2, the threshold (e.g., high-duty cycle buck exit comparator (HDEC) threshold) and the high-duty cycle request indication are inputs to the controller 208. Alternatively, one or both of the threshold and the request may be predetermined values rather than inputs.

FIG. 3 is a schematic diagram of example circuitry 300 that includes an example implementation of the switching network 120, an example implementation of the converter 104, and an example implementation of the battery 106. The example circuitry 300 includes an input VIN 302, which may be coupled to the supply 102 of FIG. 1. The example circuitry 300 also includes an output VSYS 338, which may be coupled to the load 108 of FIG. 1. The example circuitry 300 further includes a first noise cancelling capacitor 304 coupled to ground and a second noise cancelling capacitor 336 coupled to ground.

The example switching network 120 of FIG. 3 includes a resistor 306, a first transistor 308, a first diode 310, a second transistor 312, a second diode 314, a third transistor 316, a third diode 318, and a fourth transistor 320. The switching networking 120 is coupled to the controller 122 via drive signals to controller the operation of the transistors and via connections to allow the controller 122 to monitor the state of the switching network 120.

The resistor 306 includes a first terminal coupled to VIN and the first noise cancelling capacitor 304. The resistor 306 includes a second terminal coupled to a first current terminal of the first transistor 308 and a cathode terminal of the first diode 310. The first terminal of the resistor 306 is also coupled to an input terminal ACN of the controller 122. The second terminal of the resistor 306 is also coupled to an input terminal ACP of the controller 122.

The first transistor 308 includes a second current terminal coupled to an anode terminal of the first diode 310, a first current terminal of the second transistor 312, a cathode terminal of the second diode 314, a first terminal of the inductor 326, and an input SW1 of the controller 122. The first transistor 308 also includes a control terminal connected to a driver signal HIDRV1 of the controller 122.

The second transistor 312 includes a second current terminal coupled to an anode terminal of the second diode 314 and ground. The second transistor 312 also includes a control terminal connected to a driver signal LODRV1 of the controller 122.

The third transistor 316 includes a first current terminal coupled to a cathode of the third diode 318, the battery 106, the second noise cancelling capacitor 336, and the output VSYS. The third transistor 316 includes a second current terminal coupled to an anode terminal of the third diode 318, a first current terminal of the fourth transistor 320, a cathode terminal of the fourth diode 324, a second terminal of the inductor 326, and an input SW2 of the controller 122. The third transistor 316 also includes a control terminal connected to a driver signal HIDRV2 of the controller 122.

The fourth transistor 320 includes a second current terminal coupled to an anode terminal of the fourth diode 324 and ground. The fourth transistor 320 also includes a control terminal connected to a driver signal LODRV2 of the controller 122.

The controller 122 of the example of FIG. 3 illustrates circuitry for the shutoff circuit 126. An implementation of the switch driver 124 is not illustrated because example circuitry for driving switches of the switching network 120 is known to those in the field of converter development. The shutoff circuit 126 of FIG. 3 includes a first voltage divider implemented by a first resistor 350 and a second resistor 352 to implement the output voltage sensor 204. The shutoff circuit 126 of FIG. 3 includes a second voltage divider implemented by a third resistor 354 and a fourth resistor 356 to implement the input voltage sensor 202. The shutoff circuit 126 further includes a divider 358, a comparator 360, and an AND gate 362.

The first resistor 350 includes a first terminal coupled to an input terminal SYS of the controller 122 that is coupled to the output voltage VSYS of the switching network 120. The first resistor 350 includes a second terminal coupled to a first terminal of the second resistor 352 and a first input terminal of the divider 358. The second resistor 352 includes a second terminal coupled to ground.

The third resistor 354 includes a first terminal coupled to an input terminal VBUS of the controller 122 that is coupled to the input voltage VIN of the switching network 120. The third resistor 354 includes a second terminal coupled to a first terminal of the fourth resistor 356 and a second input terminal of the divider 358. The fourth resistor 356 includes a second terminal coupled to ground.

The divider 358 (e.g., divider circuit) includes an output terminal coupled to an inverting input terminal of the comparator 360. The example comparator has a nonzero deglitch time to maximize the time spent in buck mode and reduce the likelihood of unintentionally transitioning to buck-boost mode. However, in other implementations any type of comparator may be utilized. The comparator 360 includes a non-inverting input terminal coupled to a signal indicative of an HDEC threshold (e.g., a stored value, a user input, etc.). The comparator 360 includes an output terminal coupled to a first input terminal of the AND gate 362. The AND gate 362 includes a second input terminal coupled to a signal indicative of a high-duty buck request (e.g., a user input, an input controlled by a controller, etc.). The AND gate 362 includes an output terminal coupled to circuitry for implementing the switch driver 124 to indicate to the switch driver 124 whether high-duty mode is requested or if normal buck-boost mode is requested.

The battery 106 of FIG. 3 includes a diode 328, a control transistor 330, a resistor 332, and a battery 334. The control transistor 330 includes a first current terminal coupled to the output VSYS of the switching network 120 and a cathode terminal of the diode 328. The control transistor 330 includes a second current terminal coupled to an anode terminal of the diode 328, a first terminal of the resistor 332, and an input terminal SRN of the controller 122. The control transistor 330 includes a control terminal coupled to a battery driver terminal BATDRV of the controller 122.

The resistor 332 includes a second terminal coupled to a positive terminal of the battery 334 and an input terminal SRP of the controller 122. The battery includes a negative terminal coupled to ground.

In operation of the environment 300 of FIG. 3, as the battery 334 is charged by the voltage output by the switching network 120, the controller 122 monitors the input and output to control the mode of operation (e.g., buck mode, buck-boost mode, and boost mode). The controller 122 can also operate in high-duty buck mode when VOUT approaches VIN and when the shutoff circuit 126 includes that high-duty buck mode is requested. According to the example, the divider 358 of the shutoff circuit 126 divides the output voltage (e.g., a relative value of the voltage from the first voltage divider) by the input voltage (e.g., a relative value of the voltage from the second voltage divider). The comparator 360 compares the result of the divider 358 with the HDEC threshold. When the result of the divider 358 is greater than the threshold (or greater than or equal to the threshold), the comparator 360 outputs a logic low output (or other output indicative of the result of the comparison). When the result of the divider 358 is less than the threshold, the comparator 360 outputs a logic high output (or other output indicative of the result of the comparison). The AND gate 362 performs a logical AND of the output of the comparator 360 and the high-duty buck request signal. Accordingly, if high-duty buck is requested AND the comparator 360 outputs an indication that VOUT/VIN is less than the HDEC threshold, the AND gate 362 outputs an indication that high-duty buck mode is requested. Alternatively, when VOUT/VIN becomes greater than the HDEC threshold and the comparator 360 outputs a logic low, the AND gate 362 outputs an indication that normal buck-boost mode is requested (e.g., even if the high-duty buck input signal indicates that high-duty buck mode is requested). To enable high-duty cycle buck in the switching network 120 of FIG. 3, switch driver 124 will skip the low side turn on pulse for the second transistor 314 and the fourth transistor 320 and will keep the high side third transistor 316 on, effectively increasing the equivalent duty cycle and efficiency.

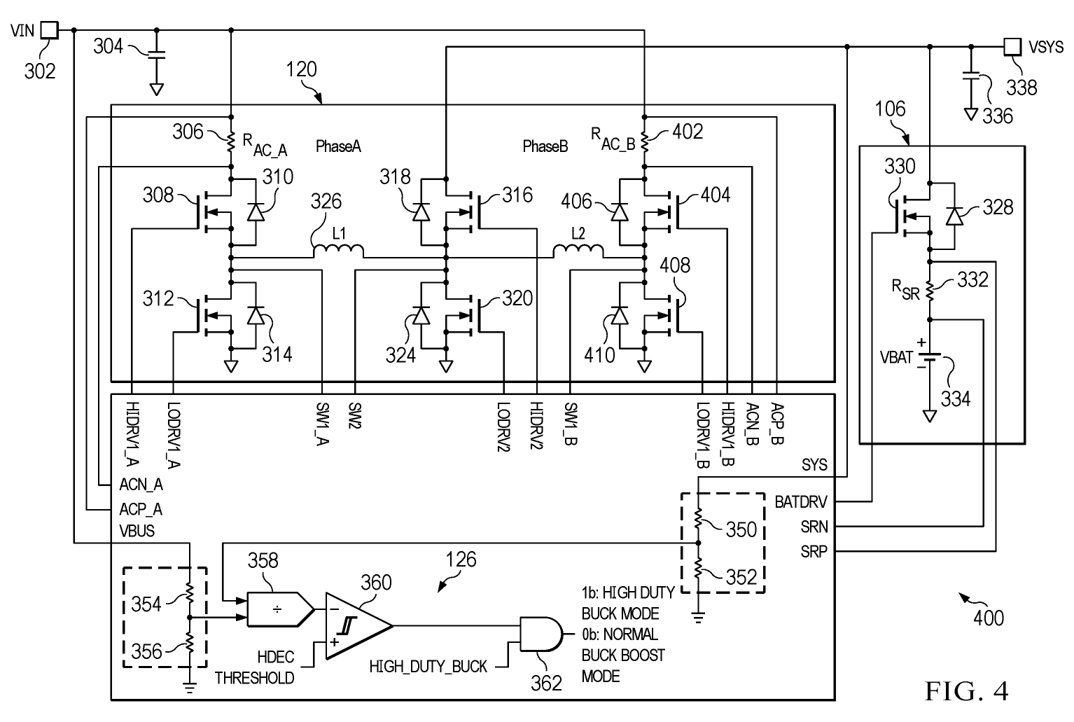

FIG. 4 is a schematic diagram of another example circuitry 400 that includes an example implementation of the switching network 120, an example implementation of the converter 104, and an example implementation of the battery 106. As compared with the circuitry 300 of FIG. 3, the switching network 120 of FIG. 4 includes additional switches to support quasi dual phase operation. For simplicity, the same components that include the same reference numbers in FIG. 3 are not described again. The switching network 120 of FIG. 4 also includes a second resistor 402, a fifth transistor 404, a fifth diode 406, a sixth transistor 408, a sixth diode 410, and a second inductor 412.

The second resistor 402 includes a first terminal coupled to the input VIN and an input terminal ACP_B of the controller 122. The second resistor 402 includes a second terminal coupled to an input terminal ACN_B of the controller 122, a first current terminal of the fifth transistor 404, and a cathode terminal of the diode 406. The fifth transistor 404 includes a second current terminal coupled to an anode terminal of the fifth diode 406, a first terminal of the second inductor 412, an input terminal SW1_B of the controller 122, a first current terminal of the sixth transistor 408, and a cathode terminal of the sixth diode 410. The fifth transistor 404 includes a control terminal coupled to an output HIDRV1_B of the controller 122.

The sixth transistor 408 includes a second current terminal coupled to an anode terminal of the sixth diode 410 and ground. The sixth transistor 408 includes a control terminal coupled to an output LODRV1_B of the controller 122.

The second inductor 412 includes a second terminal coupled to the second terminal of the inductor 326.

The shutoff circuitry 126 of FIG. 4 includes the same components as FIG. 3 and operates in the same manner. The controller 122 similarly keeps the third transistor 316 constantly enabled during high-duty buck mode.

FIG. 5 is a state diagram illustrating an operation 500 of the controller 122. According to the operation 500 when the controller 122 is initially operating in normal buck-boost mode, the switch driver 124 determines if the operation conditions VLOOP_OUT are high enough to enter continuous current mode (CCM) (block 502). For example, VLOOP_OUT is an output signal for the converter external regulation loop amplifier which may be indicative of inductor average current and may be compared against a threshold (e.g., 1 amp). If VLOOP_OUT is not high enough, the controller 122 remains in STATE 0 with normal pulse frequency modulation (PFM) buck-boost mode (block 504). When VLOOP_OUT is high enough, the controller 122 transitions to STATE 1 with Normal CCM buck-boost mode with both buck (SW1_X) and boost (SW2) half bridges switching. High-duty buck mode is disabled (HIGH_DUTY_BUCK=0b) with reduced efficiency and thermal properties (block 506). The controller 122 determines if high-duty buck mode is requested (block 508). When high-duty buck mode is enabled, the shutoff circuit 126 determines if VOUT/VIN is greater than the HDEC threshold (e.g., 99%) (block 510).

When VOUT/VIN is not greater than the HDEC threshold, the controller 122 transitions to (or remains in) STATE 2 with high-duty buck mode operation (block 512). For example, boost high side transistor 316 stays on and only SW1 (e.g., SW1_A and SW1_B) are switched in buck mode. This state may achieve better efficiency and thermal performance when a battery is fully charged and getting close to VIN.

When VOUT/VIN is greater than the HDEC threshold, the controller 122 transitions to STATE 3 with normal buck-boost mode (block 512). The system may encounter reduced efficiency and thermal conditions, but this state may prevent reverse boost-back when VIN is disconnected or reduced.

In some implementations, any time that the high-duty buck request is disabled, the controller 122 may transition back to normal buck-boost mode if it is in high-duty buck mode.

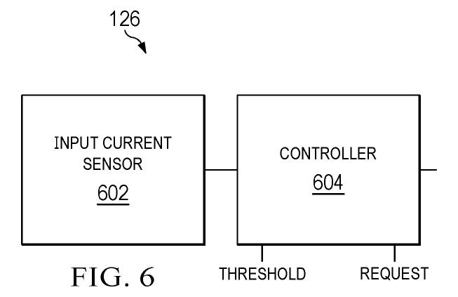

FIG. 6 is a block diagram of another example implementation of the shutoff circuit 126. The example shutoff circuity 126 of FIG. 6 includes an example input current sensor 602 and an example controller 604.

The input current sensor 602 senses the current flowing into the input of the switching network 120 and outputs an indication of the current to the controller 122. The example input current sensor 602 may be implemented by circuitry that measures a voltage drop across a sense resistor (e.g., a resistor of known resistance), by a current sensing amplifier, etc.

The controller 604 compares the current indication output by the input current sensor 602 with a threshold (e.g., a light load exit comparator (LLEC) threshold) to determine if a high-duty buck mode request is be output by the controller 604. The example controller 208 is implemented by a comparator to compare the difference with the LLEC threshold and an AND gate to perform a logical AND of the output of the comparator and an input signal indicative of a request for high-duty cycle buck mode. Alternatively, the controller 208 may be implemented by a microprocessor, a microcontroller, discrete circuit elements, or any combination. According to the example of FIG. 6, the threshold (e.g., LLEC threshold) and the high-duty cycle request indication are inputs to the controller 208. Alternatively, one or both of the threshold and the request may be predetermined values rather than inputs.

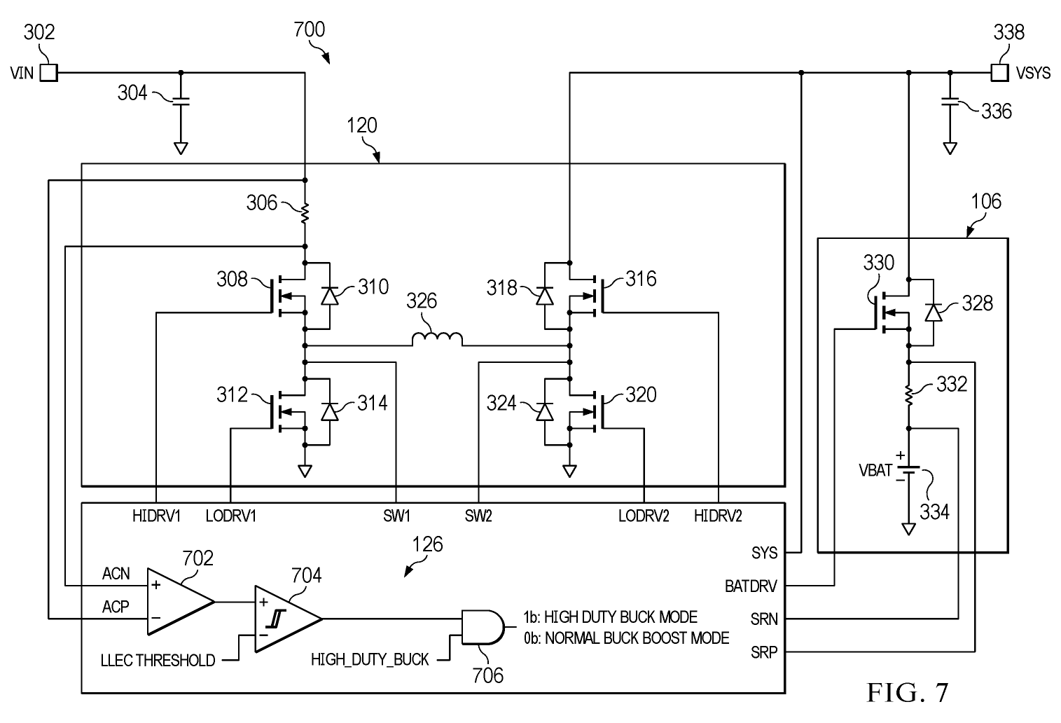

FIG. 7 is a schematic diagram of another example circuitry 700 that includes an example implementation of the switching network 120, an example implementation of the converter 104, and an example implementation of the battery 106. As compared with the circuitry 300 of FIG. 3, the switching network 120 and the battery 106 are the same and, thus, are not described again. The shutoff circuit 126 of FIG. 7 includes an amplifier 702, a comparator 704, and an AND gate 706.

The amplifier 702 is an operational amplifier to amplify a difference between a non-inverting input terminal and an inverting input terminal. Alternatively, any other type of amplifier or circuitry for determining an indication of input current to the switching network 120 may be utilized. The non-inverting terminal of the amplifier 702 is coupled to an input ACN of the controller 122, which is coupled to the second terminal of the resistor 306. The inverting terminal of the amplifier 702 is coupled to an input ACP of the controller 122, which is coupled to the first terminal of the resistor 306. The amplifier 702 includes an output terminal to output an indication of the current flowing into the switching network 120. For example, the output of the amplifier 702 may be a voltage that is proportional to the current.

The comparator 704 includes a non-inverting terminal coupled to the output terminal of the amplifier 702 and an inserting terminal coupled to a signal indicative of an LLEC threshold (e.g., a stored value, a user input, etc.). The comparator 704 includes an output terminal coupled to a first input terminal of the AND gate 706. The AND gate 706 includes a second input terminal coupled to a signal indicative of a high-duty buck request (e.g., a user input, an input controlled by a controller, etc.). The AND gate 706 includes an output terminal coupled to circuitry for implementing the switch driver 124 to indicate to the switch driver 124 whether high-duty mode is requested or if normal buck-boost mode is requested.

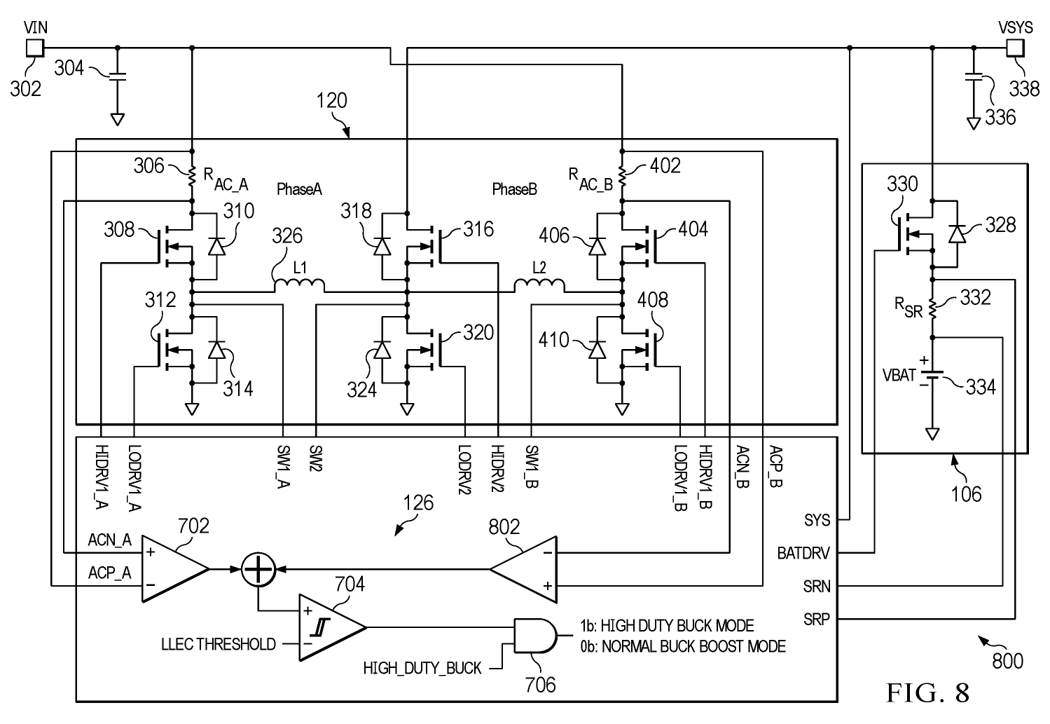

FIG. 8 is a schematic diagram of another example circuitry 800 that includes an example implementation of the switching network 120, an example implementation of the converter 104, and an example implementation of the battery 106. As compared with the circuitry 700 of FIG. 7, the switching network 120 of FIG. 8 includes additional switches to support quasi dual phase operation. For simplicity, the same components that include the same reference numbers in FIG. 4 are not described again. The components of the shutoff circuit 126 that are also in FIG. 7 are not described again. For clarity, the terminals of the controller 122 that are associated with the first phase are labeled with the suffix A and the terminals of the controller 122 that are associated with the second phase are labeled with the suffix B. The shutoff circuit 126 of FIG. 8 also includes a second amplifier 802.

The amplifier 802 of FIG. 8 includes a non-inverting input coupled to an input ACP_B to the controller 122, which is coupled to the first terminal of the second resistor 402. The amplifier 802 includes an inverting input coupled to an input ACN_B, which is coupled to the second terminal of the resistor 402. The amplifier 802 includes an output terminal to output an indication of the current flowing out of the switching network 120. For example, the output of the amplifier 702 may be a voltage that is proportional to the current.

In the shutoff circuit 126 of FIG. 8, the current indication from the amplifier 802 is combined with the current indication from the second amplifier 804 and the combination is input to the non-inverting input of the comparator 806. The current signals may be combined by a summation circuit, by connection to a common node, etc. By combining the currents, the shutoff circuit 126 can continuously monitor the current while the switching network 120 is operating in a first phase (e.g., phase A) and a second phase (e.g., phase B).

FIG. 9 is a state diagram illustrating an operation 900 of the controller 122. According to the operation 900 when the controller 122 is initially operating in normal buck-boost mode, the switch driver 124 determines if VLOOP_OUT is high enough to enter continuous current mode (CCM) (block 902). If VLOOP_OUT is not high enough, the controller 122 remains in STATE 0 with normal pulse frequency modulation (PFM) buck-boost mode (block 904). When VLOOP_OUT is high enough, the controller 122 transitions to STATE 1 with Normal CCM buck-boost mode with both buck (SW1_X) and boost (SW2) half bridges switching. High-duty buck mode is disabled (HIGH_DUTY_BUCK=0b) with reduced efficiency and thermal properties (block 906). The controller 122 determines if high-duty buck mode is requested (block 908). When high-duty buck mode is enabled, the shutoff circuit 126 determines if the input current IIN is greater than the LLEC threshold (e.g., 1 amp) (block 910).

When IIN is not greater than the LLEC threshold, the controller 122 transitions to (or remains in) STATE 2 with normal buck-boost mode (block 912). The system may encounter reduced efficiency and thermal conditions, but this state may prevent reverse boost-back when IIN is disconnected or reduced.

When IIN is greater than the LLEC threshold, the controller 122 transitions to STATE 3 with high-duty buck mode operation (block 912). For example, boost high side transistor 316 stays on and only SW1 (e.g., SW1_A and SW1_B) are switched in buck mode. This state may achieve better efficiency and thermal performance when a battery is fully charged and getting close to VIN.

In some implementations, any time that the high-duty buck request is disabled, the controller 122 may transition back to normal buck-boost mode if it is in high-duty buck mode.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may be combined, and the inclusion in different examples or claims does not imply that a combination of features is at least one of not feasible or advantageous.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/- 10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that enable a system to utilize high duty buck mode for increased efficiency, but also automatically exist high duty buck mode under certain conditions (e.g., reduced input current, VOUT approaching VIN, etc.) to avoid side effects of high duty buck mode in those conditions (e.g., a reverse feeding of power from the battery that may drain the battery over time). Described systems, apparatus, articles of manufacture, and methods are also directed to one or more improvement(s) in the operation of a machine such as a computer or other electronic, electromechanical, or mechanical device.

What is claimed is:

1. An apparatus comprising:
a comparator including a first input terminal, a second input terminal, and an output terminal, the first input terminal to be coupled to a source of a comparison of an output terminal of a buck converter and an input terminal of the buck converter, the second input terminal to be coupled to a source of a signal indicative of a threshold; and
circuitry including a first input terminal, a second input terminal, and an output terminal, the first input terminal of the circuitry coupled to the output terminal of the comparator, the second input terminal of the circuitry coupled to a signal indicative of whether a first operation mode of the buck converter is requested, the output terminal of the circuitry to indicate the first operation mode of the buck converter or a second operation mode of the buck converter.

2. The apparatus of claim 1, wherein the source of the comparison is a divider circuit including a first input terminal, a second input terminal, and an output terminal, the first input terminal of the divider circuit to be coupled to the output terminal of the buck converter, the second input terminal of the divider circuit to be coupled to the input terminal of the buck converter, and the output terminal of the divider circuit coupled to the first input terminal of the comparator.

3. The apparatus of claim 2, further including:
a first voltage divider circuit including a first resistor and a second resistor, the first resistor including a first terminal coupled to the output terminal of the buck converter, the second resistor including a first terminal coupled to a second terminal of the first resistor and the first input terminal of the divider circuit and a second terminal coupled to ground; and
a second voltage divider including a third resistor and a fourth resistor, the third resistor including a first terminal coupled to the input terminal of the buck converter, the fourth resistor including a first terminal coupled to the second terminal of the third resistor and the second input terminal of the divider circuit and a second terminal coupled to a ground terminal.

4. The apparatus of claim 1, wherein the circuitry is an AND gate.

5. The apparatus of claim 1, wherein the first operation mode of the buck converter is a high duty buck mode.

6. The apparatus of claim 5, wherein the second operation mode of the buck converter is a buck-boost mode.

7. The apparatus of claim 5, wherein the buck converter in high duty buck mode enables a high side switch for a first duration and a low side switch for a second duration that is less than the first duration.

8. The apparatus of claim 1, wherein the first input terminal of the comparator is a negative terminal and the second input terminal is a positive terminal.

9. The apparatus of claim 1, wherein the circuitry is to indicate the first operation mode in response to the output terminal of the comparator indicating the first operation mode and the signal at the second input terminal of the circuitry indicating the first operation mode.

10. The apparatus of claim 9, wherein the circuitry is to indicate the second operation mode in response to at least one of the output terminal of the comparator indicating the second operation mode or the second input terminal of the circuitry indicating the second operation mode.

11. An apparatus comprising:
a first comparator including a first input terminal, a second input terminal, and an output terminal, the first input terminal of the first comparator to be coupled to a signal indicative of an input current to a buck converter, the second input terminal of the first comparator to be coupled to a signal indicative of a threshold; and
a logic gate including a first input terminal, a second input terminal, and an output terminal, the first input terminal of the logic gate coupled to the output terminal of the first comparator, the second input terminal of the logic gate coupled to a signal indicative of whether a first operation mode of the buck converter is requested, the output terminal of the logic gate to indicate the first operation mode of the buck converter or a second operation mode of the buck converter.

12. The apparatus of claim 11, further including a second comparator including a first input terminal, a second input terminal, and an output terminal, the first input terminal of the second comparator to be coupled to a first terminal of a resistor coupled to a input to a buck converter and the second input terminal of the second comparator to be coupled to a second terminal of the resistor, the output terminal of the second comparator coupled to the first input terminal of the first comparator to provide the signal indicative of the input current to the buck converter.

13. The apparatus of claim 11, further including:
a second comparator including a first input terminal, a second input terminal, and an output terminal, the first input terminal of the second comparator to be coupled to a first terminal of a first resistor coupled to a first phase of a buck converter and the second input terminal of the second comparator to be coupled to a second terminal of the first resistor,
a third comparator including a first input terminal, a second input terminal, and an output terminal, the first input terminal of the third comparator to be coupled to a first terminal of a second resistor coupled to a first phase of a buck converter and the second terminal to be coupled to a second terminal of the second resistor; and
a summation circuit including a first input terminal, a second input terminal, and an output terminal, the first input terminal of the summation circuit coupled to the output terminal of the second comparator, the second input terminal of the summation circuit coupled to the output terminal of the third comparator, and the output terminal of the summation circuit coupled to the first input terminal of the first comparator to provide the signal indicative of the input current to the buck converter.

14. The apparatus of claim 11, wherein the output terminal of the logic gate is coupled to a controller of the buck converter to control an operating mode of the buck converter.

15. An apparatus comprising:
a buck converter circuit including a plurality of transistors to convert an input signal at a first voltage to an output signal at a second voltage;
a controller to control operation of the transistors of the buck converter circuit including controlling the buck converter circuit to operate in at least a first operation mode and a second operation mode; and
a shutoff circuit to receive an input signal indicative of a request for the first operation mode and, in response, to selectively indicate to the controller to operation in the first operation mode or the second operation mode based on the input signal.

16. The apparatus of claim 15, wherein the shutoff circuit includes:
a comparator to compare a signal indicative of a current of the input signal to a threshold; and
a logic circuit to indicate the first operation mode when the current of the input signal meets a threshold and to indicate the second operation mode when the current of the input signal does not meet the threshold.

17. The apparatus of claim 16, wherein further including a comparator to determine a difference between a voltage drop across a resistor and to output the difference as an indication of the current of the input signal.

18. The apparatus of claim 15, wherein the shutoff circuit includes:
a comparator to compare a signal indicative of a difference between an output voltage of the buck converter circuit and an input voltage of the buck converter circuit to a threshold; and
a logic circuit to indicate the first operation mode when the difference does not meet a threshold and to indicate the second operation mode when the difference meets the threshold.

19. The apparatus of claim 18, wherein the shutoff circuit includes a divider circuit to divide the output voltage by the input voltage to output the difference to the comparator.

20. The apparatus of claim 15, further including a battery coupled to the output signal of the buck converter circuit.
